(19) United States
(12) Patent Application Publication
(10) Pub. No.: US 2024/0268024 A1
(43) Pub. Date: Aug. 8, 2024

(54) SOLDER MOUNTING LAND AND CHARGER

(71) Applicant: Panasonic Automotive Systems Co., Ltd., Kanagawa (JP)

(72) Inventor: Hiroyuki HOSOI, Osaka (JP)

(21) Appl. No.: 18/635,792

(22) Filed: Apr. 15, 2024

Related U.S. Application Data
(63) Continuation of application No. PCT/JP2022/027322, filed on Jul. 11, 2022.

(30) Foreign Application Priority Data
Nov. 22, 2021 (JP) 2021-189538

(51) Int. Cl. H05K 1/11; B60L 53/22; H05K 3/34

(52) U.S. Cl. CPC H05K 1/111; B60L 53/22; H05K 3/341

(57) ABSTRACT

A solder mounting land according to the present disclosure is a land on which an electronic component is to be disposed via solder and the electronic component is to be mounted by soldering. The solder mounting land includes a first region and a second region. The first region is a regions to which the electronic component is bonded. The second region is a region protruding from a part of a peripheral edge portion of the first region in a direction in which the first region is extended in plan view.

### CROSS-REFERENCE TO RELATED APPLICATIONS

This application is a continuation of International Application No. PCT/JP2022/027322, filed on Jul. 11, 2022 which claims the benefit of priority of the prior Japanese Patent Application No. 2021-189538, filed on Nov. 22, 2021, the entire contents of which are incorporated herein by reference.

### FIELD

The present disclosure relates to a solder mounting land and a charger.

### BACKGROUND

Conventionally, there is known a technique in which a terminal of a surface-mount-type semiconductor element such as a quad flat package (QFP) or a small outline package (SOP) is soldered to a land provided on a substrate to mount the semiconductor element on the substrate by soldering.

Among these, in in-vehicle chargers, since a current value flowing between substrates is large, in order to increase bonding areas with the substrates and to reduce electric resistance, there are cases where the substrates are electrically connected by soldering a large terminal component such as a stud to each of the substrates.

Related techniques are disclosed in JP 2018-093084 A, and JP 2018-006655 A.

However, increasing the bonding area has a problem that a void is generated in which a gas generated by a reaction between flux contained in solder paste and an oxidized layer on a surface of a terminal component remains in a solder layer which is the bonding portion between a substrate and a terminal component when the component is mounted by reflow. When a void is generated at the bonding portion, the bonding area decreases, and the bonding strength decreases. For this reason, in a product in which vibration is severe such as an in-vehicle product, there is a possibility that a soldered component is separated from the substrate. In addition, sufficient bonding strength is not obtained, and it is difficult to solder-bond heavy components.

The present disclosure has an object to suppress occurrence of bonding failure in solder bonding.

### SUMMARY

A solder mounting land according to the present disclosure is a land on which an electronic component is to be disposed via solder and the electronic component is to be mounted by soldering. The solder mounting land includes a first region and a second region. The first region is a regions to which the electronic component is bonded. The second region is a region protruding from a part of a peripheral edge portion of the first region in a direction in which the first region is extended in plan view.

A solder mounting land is a land on which an electronic component is to be disposed via solder and the electronic component is to be mounted by soldering. The solder mounting land includes a first region and a groove. The first region is formed by exposing a conductive layer of a substrate from a solder resist layer stacked on an upper surface of the conductive layer. The electronic component is to be bonded to the first region. The groove is formed by exposing a layer underneath the conductive layer, and extending from an inside to a peripheral edge portion of the first region to divide the first region.

### BRIEF DESCRIPTION OF THE DRAWINGS

FIG. 1 is a cross-sectional view schematically illustrating an example of a structure of an inter-board connection portion in an in-vehicle charger according to an embodiment;

FIG. 2 is a plan view schematically illustrating an example of a structure of a solder mounting land according to a first embodiment;

FIG. 3 is a cross-sectional view schematically illustrating an example of a structure of a solder mounting land in a first region in FIG. 2;

FIG. 4 is a cross-sectional view schematically illustrating an example of a structure of the solder mounting land in a second region in FIG. 2;

FIG. 5 is a plan view schematically illustrating an example of a structure of a solder mounting land according to a second embodiment;

FIG. 6 is a cross-sectional view schematically illustrating an example of the structure of the solder mounting land in a groove of FIG. 5; and

FIG. 7 is a plan view schematically illustrating an example of a structure of a solder mounting land according to a third embodiment.

### DETAILED DESCRIPTION

Hereinafter, embodiments of a solder mounting land according to the present disclosure will be described with reference to the drawings.

Note that, in the description of the present disclosure, components having the same or substantially the same functions as those described above with respect to previously described drawings are denoted by the same reference numerals, and the description thereof may be omitted as appropriate. In addition, even in a case of representing the same or substantially the same portion, dimensions or ratios may be represented differently from each other depending on drawings. Furthermore, for example, from the viewpoint of ensuring visibility of the drawings, in the description of each drawing, only major components are denoted by reference numerals, and even components having the same or substantially the same functions as those described in previous drawings may not be denoted by reference numerals.

Note that a solder mounting land according to the present disclosure is a land provided on a circuit board in which an electronic component to be connected is to be disposed via solder and to be mounted on the circuit board nu soldering.

For example, the electronic component is a terminal component for electrically connecting circuit boards such as a stud or a lug. Alternatively, the electronic component may be a component such as a semiconductor element, a semiconductor module, a magnetic body, a capacitor, or a circuit breaker. The semiconductor module includes, for example, a plurality of semiconductor elements. Incidentally, the magnetic body is a transformer, a transformer-integrated printed circuit board, an impedance transformer, a reactor, or a choke. The circuit breaker is a relay or a fuse.

For example, the circuit board is a printed circuit board (PCB). The printed circuit board is, for example, a glass epoxy substrate formed using an aluminum alloy or a copper alloy as a base material. Note that the circuit board may be included in a magnetic component such as a transformer, an impedance transformer, a reactor, or a choke. This magnetic component has, for example, a substrate on which a conductor pattern forms a winding and has a function as a magnetic component with a magnetic core penetrating through the inside and outside the winding formed on the substrate to form a closed magnetic path. In this case, the electronic component can be expressed as a printed circuit board transformer or a transformer-integrated printed circuit board.

Note that the circuit boards may be a circuit board included in a board unit. Incidentally, the board unit refers to a plurality of circuit boards that is coupled. Note that, in the board unit, the plurality of circuit boards may be coupled by solder bonding using a solder mounting land according to the present disclosure or may be coupled by an adhesive, a screw, a bolt, or the like. Furthermore, in the board unit, the coupled circuit boards may be electrically connected or insulated. Moreover, the board unit may be a circuit board on which electronic components are mounted. In this case, the electronic components and the circuit board may be electrically connected, insulated, or only thermally connected.

As an example, a circuit board or an electronic component provided with a mounting land is a component included in a power conversion device. The power conversion device is, for example, an in-vehicle charger that is mounted on an electric vehicle or the like, converts AC power supplied from a power supply (external power supply) into DC power of a predetermined voltage, and outputs the DC power after the conversion to a battery such as a lithium-ion battery. Such a power conversion device includes a plurality of circuit boards on which circuit configurations such as a DC/DC converter or an inverter are mounted. Note that a solder mounting land according to the present disclosure may be applied to electrical connection between a DC/DC converter module or an inverter module and a circuit board.

In the following description, a solder mounting land according to the present disclosure will be described by taking an example of an inter-board connection for electrically connecting a plurality of printed circuit boards mounted on an in-vehicle charger 1.

### First Embodiment

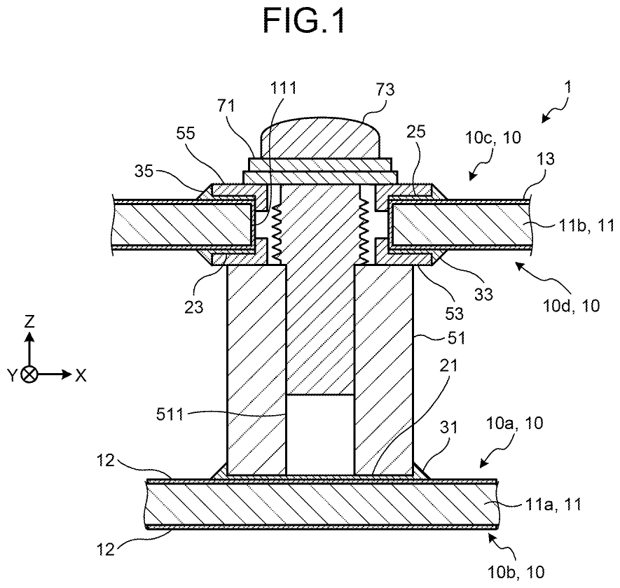

FIG. 1 is a cross-sectional view schematically illustrating an example of a structure of an inter-board connection portion in an in-vehicle charger 1 according to an embodiment. Illustrated in FIG. 1 is an example of a first circuit board 11a and a second circuit board 11b among a plurality of circuit boards 11 included in the in-vehicle charger 1. In FIG. 1, a direction from the first circuit board 11a towards the second circuit board 11b is defined as a +Z direction. The main surfaces of the first circuit board 11a and the second circuit board 11b are each parallel to an X-Y plane perpendicular to the Z direction.

The first circuit board 11a and the second circuit board 11b are, for example, each a printed circuit board. The first circuit board 11a and the second circuit board 11b are each provided with solder mounting lands 10. A solder mounting land 10 is a land on which an electronic component is disposed via solder paste in a component mounting step and on which the electronic component is mounted by soldering through reflow.

The solder paste includes solder that is a metal filler having a melting point lower than that of a base material and a flux that removes an oxidized layer formed on a surface of the solder and the base material.

In the example illustrated in FIG. 1, a solder mounting land 10a is provided on one of the main surfaces (a main surface on the +Z side in FIG. 1) of the first circuit board 11a. In the component mounting step, a stud 51 is disposed on the solder mounting land 10a provided on the main surface on the +Z side of the first circuit board 11a via the solder paste, and the stud 51 is mounted by reflow. In this manner, a bonding surface 21 of the stud 51 is soldered to the solder mounting land 10a by solder 31. The stud 51 is a cylindrical electronic component. A screw thread is formed in a hole 511 of the stud 51. Details of the solder mounting land 10a will be described later.

Moreover, in the example illustrated in FIG. 1, a solder mounting land 10b is provided on the other main surface (main surface on the-Z side in FIG. 1) of the first circuit board 11a. In the component mounting step, a desired electronic component (not illustrated) is disposed on the solder mounting land 10b provided on the main surface on the −Z side of the first circuit board 11a via the solder paste, and the electronic component is mounted by reflow. In this manner, a desired electronic component (not illustrated) can be soldered to the solder mounting land 10b.

Furthermore, in the example illustrated in FIG. 1, a solder mounting land 10c is provided on one of the main surfaces (main surface on the +Z side in FIG. 1) of the second circuit board 11b. The solder mounting land 10c is provided on the outer edge portion of a hole 111 of the second circuit board 11b. In the component mounting step, a lug 55 is disposed on the solder mounting land 10c provided on the main surface on the +Z side of the second circuit board 11b via the solder paste, and the lug 55 is mounted by reflow. The lug 55 is an electronic component having an annular shape that covers the +Z side of the outer edge portion of the hole 111 of the second circuit board 11b. In this manner, a bonding surface 25 of the lug 55 is soldered to the solder mounting land 10c by solder 35.

Furthermore, in the example illustrated in FIG. 1, a solder mounting land 10d is provided on the other main surface (main surface on the −Z side in FIG. 1) of the second circuit board 11b. The solder mounting land 10d is provided on the outer edge portion of the hole 111 of the second circuit board 11b. In the component mounting step, a lug 53 is disposed on the solder mounting land 10d provided on the main surface on the-Z side of the second circuit board 11b via the solder paste, and the lug 53 is mounted by reflow. The lug 53 is an electronic component having an annular shape that covers the −Z side of the outer edge portion of the hole 111 of the second circuit board 11b. In this manner, a bonding surface 23 of the lug 53 is soldered to the solder mounting land 10d by solder 33.

In addition, in the example illustrated in FIG. 1, a screw 73 inserted into the hole 111 of the second circuit board 11b is fastened to the stud 51 in a state where the lug 53 is in contact with the stud 51, whereby the first circuit board 11a and the second circuit board 11b are coupled. Specifically, due to the fastening force in the Z direction generated by the screw 73 and the stud 51, the washer 71 inserted between the screw 73 and the lug 55 and the Z+side surface of the stud 51 soldered to the first circuit board 11a sandwich the lug 53 and the lug 55 soldered to the second circuit board 11b. In this manner, the first circuit board 11a and the second circuit board 11b are electrically connected via the stud 51 and the lug 53.

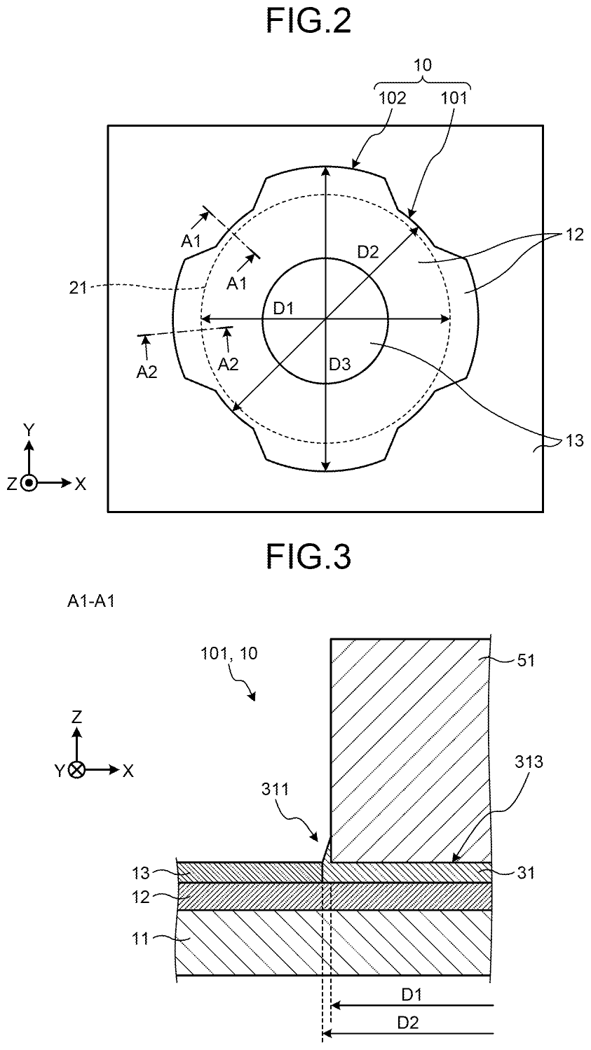

Hereinafter, the solder mounting lands 10 according to the present embodiment will be described in detail with reference to FIGS. 2 to 4.

FIG. 2 is a plan view schematically illustrating an example of the structure of the solder mounting land 10a according to the first embodiment. Illustrated in FIG. 2 is an example where the first circuit board 11a of FIG. 1 is viewed in plan view from the +Z side.

As illustrated in FIG. 2, the solder mounting land 10a has a first region 101 and a second region 102.

The first region 101 is a region to which the stud 51 as an electronic component is bonded. The first region 101 has a shape conforming to the shape of a bonding surface of an electronic component to be bonded.

In the example illustrated in FIG. 2, the stud 51, which is the electronic component to be bonded, has a cylindrical shape. In this case, as illustrated in FIG. 2, the first region 101 has an annular shape conforming to the shape of the bonding surface 21 of the stud 51 having the cylindrical shape.

The second region 102 protrudes from a part of the peripheral edge portion of the first region 101 in a direction in which the first region 101 is extended. Incidentally, the peripheral edge portion includes an inner edge portion which is a peripheral edge portion closer to the center of the first region 101 and an outer edge portion which is a peripheral edge portion opposite to the center of the first region 101. In addition, the second region 102 is a region not overlapping the first region 101 in plan view as viewed from the Z direction, namely, a direction perpendicular to the main surfaces of the first circuit board 11a. In other words, the second region 102 protrudes from a part of the peripheral edge portion of the first region 101 in a direction in which the first region 101 is extended in plan view.

In the example illustrated in FIG. 2, the second region 102 is a region protruding in a direction in which the first region 101 is extended from a part of the outer edge portion, namely, in a direction away from the center of the annular shape, from the peripheral edge portion of the first region 101 having the annular shape.

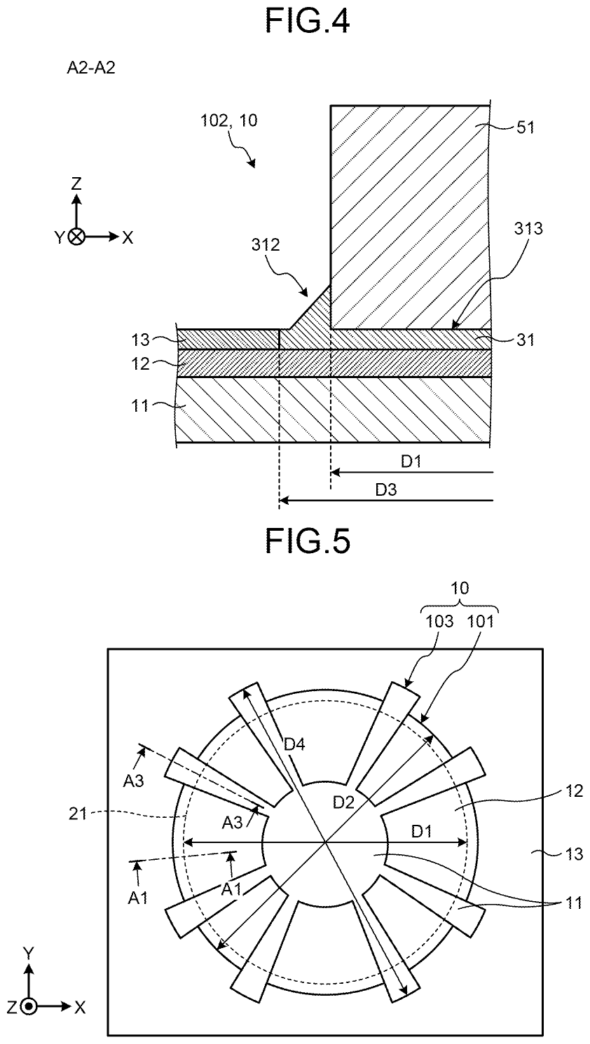

FIG. 3 is a cross-sectional view schematically illustrating an example of the structure of the solder mounting land 10 in the first region 101 of FIG. 2. In FIG. 3, illustrated is an example of A1-A1 cross section of FIG. 2. FIG. 4 is a cross-sectional view schematically illustrating an example of the structure of the solder mounting land 10 in the second region 102 of FIG. 2. In FIG. 4, illustrated is an example of A2-A2 cross section of FIG. 2.

As illustrated in FIGS. 2 to 4, the solder mounting land 10a includes a region of a conductive layer 12 and a solder resist layer 13 provided on a peripheral edge portion of the conductive layer 12.

As illustrated in FIGS. 3 and 4, the conductive layer 12 is a layer of a conductor provided on the circuit board 11. As the conductor forming the conductive layer 12, for example, copper is used; however, other conductors such as gold or aluminum may be used. As an example, the conductive layer 12 has a thickness of about 70 μm.

As illustrated in FIGS. 3 and 4, the solder resist layer 13 is a layer of solder resist provided on the conductive layer 12. As the solder resist forming the solder resist layer 13, for example, an epoxy resin is used; however, other solder resist may be used. As an example, the solder resist layer 13 has a thickness of about 30 to 35 μm.

As an example, the solder resist layer 13 is formed in such a manner as to cover the conductive layer 12 and then is formed by being removed at the first region 101 and the second region 102. Note that the solder resist layer 13 may be formed only in a region excluding the first region 101 and the second region 102. In this case, the conductive layer 12 may not be provided in the region excluding the first region 101 and the second region 102, and there may be a portion where the solder resist layer 13 is formed on the circuit board 11.

As described above, the first region 101 and the second region 102 of the solder mounting land 10a are each formed by exposing the conductive layer 12 of the circuit board 11 from the solder resist layer 13 stacked on the upper surface of the conductive layer 12. That is, the first region 101 and the second region 102 of the solder mounting land 10a are regions surrounded by an end of the solder resist layer 13 and are recessed in the Z direction from the solder resist layer 13.

Incidentally, an outer diameter D2 of the first region 101 has a size corresponding to an outer diameter D1 of the bonding surface of the electronic component to be bonded. The outer diameter D2 of the first region 101 is specified depending on, for example, the dimensional tolerance of the outer diameter D1 of the electronic component to be bonded and the mounting position accuracy of the electronic component. Specifically, the outer diameter D2 of the first region 101 is longer than or equal to a length obtained by adding the dimensional tolerance of the bonding surface of the electronic component to the outer diameter D1 of the electronic component to be bonded. In addition, the outer diameter D2 of the first region 101 is less than or equal to the length obtained by adding the mounting position accuracy required for the electronic component, namely, a deviation amount of the arrangement position allowed for the electronic component to the outer diameter D1 of the electronic component to be bonded.

For example, the first region 101 has a shape obtained by extending the outer shape of the bonding surface of the electronic component by the deviation amount of the arrangement position allowed for the electronic component to be bonded. As an example, in a case where the outer diameter D1 of the stud 51 is ϕ7.0±0.1 mm and the requirement of the mounting position accuracy is ±0.15 mm, the first region 101 has a hollow annular shape in plan view with the outer diameter D2 of ϕ7.1 to 7.15 mm.

An outer diameter D3 of the second region 102 is larger than the outer diameter D2 of the first region 101. That is, the length from the bonding surface 21 of the electronic component to be bonded to the end of the solder resist layer 13 in the second region 102 (the difference between the outer diameter D3 and the outer diameter D1) is longer than a corresponding length in the first region 101 (the difference between the outer diameter D2 and the outer diameter D1). Therefore, when the component is mounted by reflow, a fillet 312 formed between the peripheral edge portion of the electronic component and the end of the solder resist layer 13 by the solder paste provided in the second region 102 is larger than a fillet 311 formed between the peripheral edge portion of the electronic component and the end of the solder resist layer 13 by the solder paste provided in the first region 101.

The shape and the size of the second region 102, namely, the length from the peripheral edge portion of the electronic component to the end of the solder resist layer 13 in the second region 102 and the length in the direction along the peripheral edge portion of the electronic component or the peripheral edge portion of the first region 101 may be determined depending on, for example, the size of a fillet formed on the peripheral edge portion of the electronic component to be bonded by solder. Here, the size of the fillet formed on the peripheral edge portion of the electronic component to be bonded can be determined, for example, depending on the strength required for solder bonding. In addition, the shape and the size of the second region 102 can be determined depending on, for example, how easy it is to remove a void that occurs at the time of solder bonding. That is, the shape and the size of the second region 102 are only required to be specified on the basis of the amount of solder required for forming a desired fillet and how easy it is to remove a void that occurs during at the time of reflow.

For example, a peripheral edge portion opposite to the first region 101 out of the peripheral edge portion of the second region 102 has a shape following the shape of the peripheral edge portion of the corresponding first region 101, from which the second region 102 protrudes as illustrated in FIG. 2. In other words, each of the first region 101 and the second region 102 forming the peripheral edge portion of the solder mounting land 10 has a shape conforming to the outer shape of the electronic component to be bonded. It goes without saying that the second region 102 may have a shape not conforming to the outer shape of the electronic component to be bonded. As an example, in a case where the outer diameter D1 of the stud 51 is ϕ7.0±0.1 mm and the outer diameter D2 of the first region 101 is ϕ7.1 to 7.15 mm, the second region 102 is a part of a circular outer edge portion having an outer diameter D3 of ϕ8.0 mm.

Note that, in the present embodiment, for simplicity of explanation, a case where the first region 101 and the second region 102 are positioned on the same plane is illustrated as an example; however, it is not limited thereto. The second region 102 may be provided in a plane different from that of the first region 101. That is, the second region 102 may protrude from a part of the peripheral edge portion of the first region 101 in a direction in which the first region 101 is extended in plan view on a plane different from that of the first region 101 or in such a manner as to have an inclination with respect to the first region 101.

Note that, in the present embodiment, the cylindrical stud 51 has been illustrated as an example as the electronic component to be bonded; however, it is not limited thereto. In the solder mounting land 10 according to the present embodiment, an electronic component having another shape can also be used as an electronic component to be bonded.

For example, in a case where the electronic component to be bonded has a solid round bonding surface 21, the first region 101 has a solid round shape conforming to the bonding surface 21 of the electronic component to be bonded. Meanwhile, the second region 102 protrudes from a part of the outer edge portion of the first region 101 in a direction in which the first region 101 is extended in plan view.

For example, in a case where the electronic component to be bonded has a bonding surface 21 having a solid polygonal shape such as a solid rectangular shape, the first region 101 has a solid polygonal shape conforming to the bonding surface 21 of the electronic component to be bonded. Meanwhile, the second region 102 protrudes from a part of the outer edge portion of the first region 101 in a direction in which the first region 101 is extended in plan view.

For example, in a case where the electronic component to be bonded has a bonding surface 21 having a hollow polygonal shape in plan view, the first region 101 has a hollow polygonal shape in plan view conforming to the bonding surface 21 of the electronic component to be bonded. Meanwhile, the second region 102 protrudes from a part of the peripheral edge portion of the first region 101 in a direction in which the first region 101 is extended in plan view.

In a case where the first region 101 is a hollow region in plan view, the second region 102 may protrude from a part of the inner edge portion of the peripheral edge portion of the first region 101 in a direction in which the first region 101 is extended, namely, in a direction towards the center of the annular shape, instead of the outer edge portion. In addition, the second region 102 may protrude from a part of each of the outer edge portion and the inner edge portion of the first region 101 in directions in which the first region 101 is extended. In other words, in a case where the first region 101 has an annular shape, the second region 102 protrudes from at least one of the inner edge portion or the outer edge portion of the first region 101.

Note that, in a case where the electronic component to be bonded has a hollow circular shape or polygonal shape in plan view, namely, an annular bonding surface 21, the first region 101 is not limited to a hollow region and may be a solid region in plan view. Furthermore, in a case where the electronic component to be bonded has a solid bonding surface 21 in plan view, the first region 101 is not limited to a solid region and may be a hollow region in plan view. In these cases, the second region 102 protrudes from a part of the outer edge portion of the first region 101 in a direction in which the first region 101 is extended in plan view.

In general, there are cases where an in-vehicle device such as the in-vehicle charger 1 has a high mounting density of electronic components and includes a plurality of circuit boards that is stacked, for example, in response to a demand for miniaturization. In a case where a plurality of electronic components is densely arranged or a plurality of circuit boards is stacked, there is a high requirement for the mounting accuracy of electronic components on a circuit board, and an allowable amount of positional deviation is small. However, there are cases where the electronic components are moved due to wet-spreading of the solder paste at the time of reflow, whereby the mounting accuracy may be deteriorated.

Under such circumstances, the solder mounting land 10 according to the present embodiment has the first region 101 having a shape obtained by slightly extending the outer shape of the electronic component to be bonded such as the stud 51 depending on the dimensional tolerance of the electronic component and the mounting positional accuracy of the electronic component. As a result, it is possible to suppress movement of the electronic component due to wet-spreading of the solder paste at the time of reflow.

In addition, in an in-vehicle device, for example, a special solder paste that can suppress deterioration due to a high operating temperature or stress associated with a cooling and heating cycle may be used. Solder paste used in such in-vehicle devices may have low fluidity at the time of reflow. In addition, since a large current flows in the in-vehicle charger 1 mounted on a hybrid vehicle or an EV vehicle, a bonding area of solder bonding may be large. For this reason, in a case where a component having a large bonding area is soldered in an in-vehicle device, a large amount of voids is particularly likely to be generated, and the quality of the solder joint may deteriorate with the generation of voids.

In addition, the solder mounting land 10 according to the present embodiment has the second region 102 protruding from a part of the peripheral edge portion of the first region 101 and has a shape in which the part of the peripheral edge portion is extended. In the extended portion, namely, in the second region 102, the length from the peripheral edge portion of the electronic component to be bonded to the end of the solder resist layer 13 is larger than that in the first region 101. When the component is mounted by reflow, a gas generated in a solder bonding portion 313 due to a reaction between the flux contained in the solder paste and an oxidized layer on a component surface such as a terminal of the electronic component is easily released to the outside. As a result, it is possible to suppress the gas generated in the solder bonding from remaining in the solder bonding portion 313 to form a void.

Furthermore, in the extended portion, the fillet 312 having a sufficient size can be formed using more solder paste than in the non-extended portion and using a space wider than in the non-extended portion.

As described above, according to the solder mounting land 10 of the present embodiment, it is possible to ensure sufficient bonding strength and high mounting position accuracy while suppressing generation of voids in the solder bonding portion 313. In other words, the solder mounting land 10 according to the present embodiment can suppress the occurrence of a bonding failure in solder bonding.

### Second Embodiment

In the first embodiment, the solder mounting land 10 having the second region 102 protruding from a part of the peripheral edge portion of the first region 101 and having a shape in which the part of the peripheral edge portion is extended has been described; however, it is not limited thereto. In the present embodiment, instead of including the second region 102 obtained by extending the peripheral edge portion of the first region 101, a solder mounting land 10 that can suppress occurrence of a bonding failure in solder bonding by including grooves 103 that each spatially connect a part of a peripheral edge portion of a first region 101 with another part will be described.

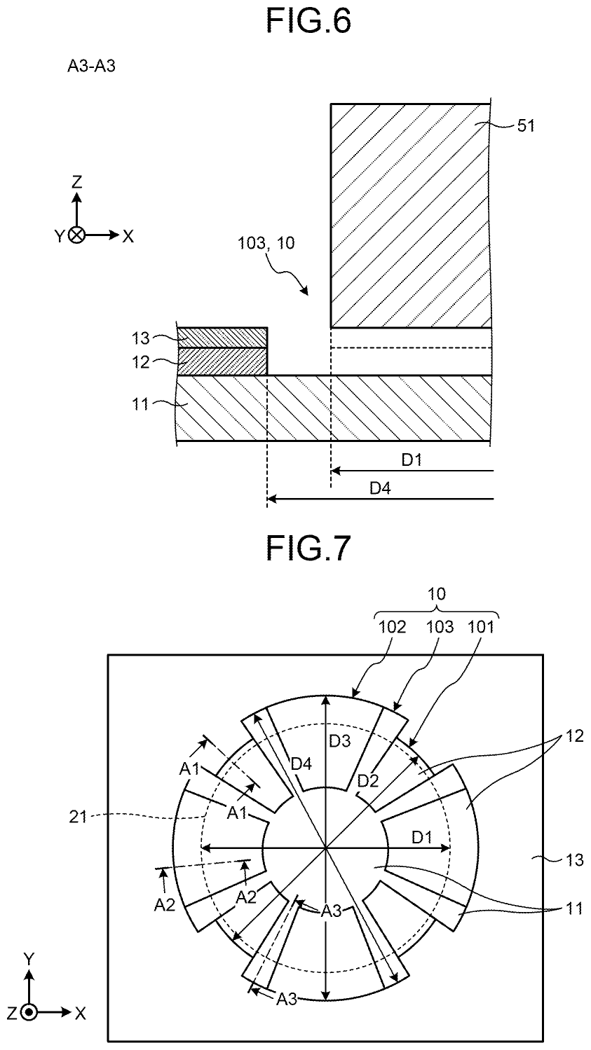

FIG. 5 is a plan view schematically illustrating an example of a structure of a solder mounting land 10 according to a second embodiment. Illustrated in FIG. 5 is an example where the first circuit board 11a of FIG. 1 is viewed in plan view from the +Z side. FIG. 6 is a cross-sectional view schematically illustrating an example of the structure of the solder mounting land 10 in a groove 103 of FIG. 5. In FIG. 6, illustrated is an example of A3-A3 cross section of FIG. 2.

As illustrated in FIG. 5, the solder mounting land 10 according to the present embodiment has the first region 101 and the grooves 103. Meanwhile, unlike the solder mounting land 10 according to the first embodiment, the solder mounting land 10 according to the present embodiment does not have a second region 102.

Similarly to the solder mounting land 10 according to the first embodiment, the first region 101 is a region to which a stud 51 as an electronic component to be bonded is bonded and has a shape conforming to the shape of a bonding surface 21 of the stud 51. The first region 101 is formed by exposing a conductive layer 12 of a circuit board 11 from a solder resist layer 13 stacked on the upper surface of the conductive layer 12.

The grooves 103 divide the first region 101. A groove 103 spatially connects a part of the peripheral edge portion of the first region 101 and another part of the peripheral edge portion of the first region 101. A groove 103 extends from the inside of the first region 101 to a position protruding from the peripheral edge portion. In the example illustrated in FIG. 5, the grooves 103 extend from the central portion of the first region 101, namely, a position protruding from the inner edge portion to a position protruding from the outer edge portion. In addition, in the example illustrated in FIG. 5, the grooves 103 include a plurality of pairs of grooves each formed linearly. A length D4 of a pair of grooves 103 formed linearly is larger than an outer diameter D2 of the first region 101, for example.

For example, as illustrated in FIGS. 5 and 6, in a case where the bonding surface 21 of the electronic component to be bonded has a hollow annular shape in plan view, the grooves 103 spatially connect the inner edge portion and the outer edge portion of the first region 101. That is, a groove 103 is spatially connected with another groove 103 in the inside of the first region 101, more specifically, via a region inside the inner edge portion of the first region 101. Alternatively, even in a case where the bonding surface 21 has a solid shape in plan view, if the first region 101 has a hollow annular shape in plan view, the groove 103 spatially connects the inner edge portion and the outer edge portion of the first region 101. Alternatively, the grooves 103 may each spatially connect a part of the inner edge portion of the first region 101 and another part of the inner edge portion or may spatially connect a part of the outer edge portion and another part of the outer edge portion.

For example, in a case where the bonding surface 21 of the electronic component to be bonded has a solid shape in plan view, the grooves 103 each spatially connects the inside of the first region 101, typically, the central portion, and the outer edge portion of the first region 101. Alternatively, a groove 103 may spatially connect a part of the outer edge portion of the first region 101 and another part of the outer edge portion. Note that a groove 103 may be spatially connected with another groove 103 in the inside of the first region 101 regardless of the shape of the first region 101.

The grooves 103 are formed by exposing a layer underneath the conductive layer 12. As an example, the grooves 103 are formed by removing the conductive layer 12 and the solder resist layer 13 in the circuit board 11 on which the conductive layer 12 and the solder resist layer 13 are stacked.

As illustrated in FIG. 6, when the electronic component to be bonded is soldered, the grooves 103 form a gap having a height corresponding to the thicknesses of the conductive layer 12 and the solder resist layer 13 between the electronic component and the circuit board 11. The gap is a space in contact with the end of the first region 101 divided by the grooves 103 and forms a space in contact with an end of solder paste provided in the first region 101.

Note that, in the present embodiment, as illustrated in FIG. 5, a case where a plurality of grooves is formed as the grooves 103 has been illustrated as an example; however, it is not limited thereto. It is required that at least one groove 103 be included.

In addition, in the present embodiment, as illustrated in FIG. 5, the grooves 103 each spatially and linearly connecting a part of the outer edge portion and another part of the outer edge portion via a hollow central portion of the first region 101 have been illustrated; however, it is not limited thereto. The two grooves 103 spatially connecting the inner edge portion and the outer edge portion of the first region 101 may not be arranged linearly. Similarly, the number of grooves formed as the grooves 103 is not limited to an even number and may be an odd number.

Note that, as illustrated in FIG. 5, the grooves 103 are formed, for example, radially regardless of the shape of the first region 101. In this case, each of the grooves 103 is not limited to be linear and may be curved, for example, for the reason of suppressing the outflow of flux.

Furthermore, the grooves 103 are not limited to the case of being formed radially and may include first grooves formed radially and a second groove formed concentrically regardless of the shape of the first region 101. The first grooves formed concentrically and the second groove formed radially are spatially connected. Note that it is only required that at least one first groove and at least one second groove be formed.

Furthermore, the grooves 103 may be formed in a lattice pattern regardless of the shape of the first region 101. Note that, among the grooves 103 formed in the lattice pattern, grooves 103 having different directions may be orthogonal or may not be orthogonal to each other. Furthermore, the grooves 103 are not limited to being formed in the lattice pattern and may be arranged only in any one direction.

Note that the grooves 103 may include a groove that is not spatially connected to the peripheral edge portion of the first region 101. Since the gas generated at the time of reflow can be stored even with this structure, the effect of suppressing a void can be obtained.

As described above, the solder mounting land 10 according to the present embodiment has the grooves 103 that extend from the inside of the first region 101 to the peripheral edge portion to divide the first region 101. This makes it possible to easily release the gas generated at the time of reflow from the grooves 103 adjacent to the solder bonding portion 313, whereby voids are reduced, which can improve the peeling strength of solder bonding. In other words, occurrence of a bonding failure in solder bonding can be suppressed.

Moreover, in the solder mounting land 10 according to the present embodiment, the first region 101 is formed by exposing the conductive layer 12 from the solder resist layer 13 stacked on the upper surface of the conductive layer 12, whereas the grooves 103 are formed by exposing a layer underneath the conductive layer 12. As a result, the grooves 103 are not applied with the solder paste, and the cross-sectional area as a slit can be increased, and thus the grooves act as a slit through which the gas generated at the time of reflow is easily released. Therefore, the solder mounting land 10 according to the present embodiment can suppress the occurrence of a bonding failure in solder bonding.

Note that the shape, the size, and the number of the grooves 103 may be determined as appropriate in trade-off between a decrease in the bonding area due to the grooves 103 and an increase in the peeling strength accompanying a decrease in residual voids in the solder bonding portion 313.

### Third Embodiment

Note that the solder mounting land 10 according to the first embodiment and the solder mounting land 10 according to the second embodiment can be combined as appropriate.

FIG. 7 is a plan view schematically illustrating an example of a structure of a solder mounting land 10 according to a third embodiment. As illustrated in FIG. 7, the solder mounting land 10 according to the present embodiment has a second region 102 protruding from a part of a peripheral edge portion of a first region 101 and grooves 103 each spatially connecting a part of the peripheral edge portion of the first region 101 with another part.

In the solder mounting land 10 according to the present embodiment, as illustrated as an example in FIG. 7, the second region 102 is formed in such a manner as to protrude from the peripheral edge portion of the first region 101 between a pair of adjacent grooves 103.

Note that, in FIG. 7, a case where an outer diameter D3 of the second region 102 is equal to a length D4 of a pair of grooves 103 formed linearly is illustrated as an example; however, the outer diameter D3 and the length D4 may be different. That is, as an example, a groove 103 extends to a peripheral edge portion of an adjacent second region 102. As another example, a groove 103 extends to a position protruding from a peripheral edge portion of an adjacent second region 102. As another example, a groove 103 extends to a position not protruding from a peripheral edge portion of an adjacent second region 102.

In addition, in FIG. 7, a case where the second region 102 and the grooves 103 are adjacent to each other is illustrated as an example; however, it is not limited thereto. The second region 102 provided between a pair of adjacent grooves 103 may be formed at a position spatially separated from at least one of the pair of adjacent grooves 103.

Note that the second region 102 may not be formed between a pair of adjacent grooves 103.

As described above, the solder mounting land 10 according to the present embodiment includes the second region 102 protruding from a part of the peripheral edge portion of the first region 101 and the grooves 103 each spatially connecting a part of the peripheral edge portion of the first region 101 with another part, whereby occurrence of a bonding failure in solder bonding can be suppressed.

More specifically, while the grooves 103 suppress residual voids in the solder bonding portion 313, a decrease in the bonding area and a decrease in the bonding strength due to the formation of the grooves 103 can be alleviated by forming a large fillet with the second region 102. In addition, by forming the second region 102 and the grooves 103, a degassing path can be sufficiently ensured. In addition, since the second region 102 is provided only on a part of the outer periphery of the solder mounting land 10, it is possible to achieve an effect of suppressing deviation of the mounting position in a portion where no second region 102 is provided.

Note that in each of the above embodiments, the solder mounting land 10a provided on one of the main surfaces (main surface on the +Z side in FIG. 1) of the first circuit board 11a has been illustrated as an example; however, solder mounting lands 10 other than the solder mounting land 10a can have a similar structure to that of the solder mounting land 10a according to each of the above embodiments. For example, at least one of the solder mounting land 10c or the solder mounting land 10d can have a structure similar to that of the solder mounting land 10a described below. This makes it possible to suppress occurrence of a bonding failure in solder bonding between a second circuit board 11b and a lug 53 and/or a lug 55.

Note that in each of the above embodiments, the solder bonding between one stud 51 and the first circuit board 11a has been described as an example for simplicity of description; however, it is not limited thereto. A plurality of solder mounting lands 10 may be provided on the first circuit board 11a, for example, by soldering a pair of circuit boards 11 by a plurality of studs 51. Moreover, each circuit board 11 may be provided with two or more pairs of solder mounting lands 10 for coupling two or more circuit boards 11 to one main surface. Furthermore, each circuit board 11 may be provided with two or more types of solder mounting lands 10 for soldering two or more types of electronic components on one main surface.

In each of the above-described embodiments, in a case where the peripheral edge portion of the first region 101 has a polygonal outer shape, the second region 102 preferably protrudes in a direction in which the first region 101 is extended in plan view from a part other than corner portions of the polygonal shape in the outer edge portion of the first region 101. Alternatively, in a case where the second region 102 is included at a corner of the outer edge portion of the first region 101, it is preferable that no second region 102 be included at a part of the sides adjacent to the corner of the peripheral edge portion of the first region 101. With this structure, it is possible to limit the amount of positional deviation of the electronic component to be bonded as the solder paste flows during reflow, and thus the deviation amount of the arrangement position of the electronic component can be reduced.

According to at least one of the embodiments described above, the occurrence of bonding failure in solder bonding can be suppressed.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

### Supplement

The following techniques are disclosed by the above description of the embodiments.

### (Technique 1)

A solder mounting land on which an electronic component is to be disposed via solder and the electronic component is to be mounted by soldering, the solder mounting land including:
a first region to which the electronic component is bonded; and
a second region protruding from a part of a peripheral edge portion of the first region in a direction in which the first region is extended in plan view.

### (Technique 2)

The solder mounting land according to Technique 1, further including a groove that extends from an inside to the peripheral edge portion of the first region to divide the first region.

### (Technique 3)

The solder mounting land according to Technique 1, further including:
a plurality of grooves each extending from an inside to the peripheral edge portion of the first region to divide the first region,
wherein the second region protrudes from the peripheral edge portion of the first region between at least one pair of adjacent grooves among the plurality of grooves.

### (Technique 4)

A solder mounting land on which an electronic component is to be disposed via solder and the electronic component is to be mounted by soldering, the solder mounting land including:
a first region formed by exposing a conductive layer of a substrate from a solder resist layer stacked on an upper surface of the conductive layer, the electronic component being to be bonded to the first region;
a plurality of grooves formed by exposing a layer underneath the conductive layer, and each extending from an inside to a peripheral edge portion of the first region to divide the first region; and
a second region protruding from the peripheral edge portion of the first region between at least one pair of adjacent grooves among the plurality of grooves.

### (Technique 5)

The solder mounting land according to Technique 3 or 4, wherein a groove adjacent to the second region extends from the inside of the first region to a peripheral edge portion of the second region.

### (Technique 6)

The solder mounting land according to any one of Technique 3 to 5, wherein
the first region has an annular shape that is hollow in plan view, and
each of the plurality of grooves radially extends from an inner edge portion to an outer edge portion of the first region.

### (Technique 7)

The solder mounting land according to any one of Technique 3 to 5, wherein
the first region has a round shape, and
each of the plurality of grooves radially extends from a central portion to an outer edge portion of the first region.

### (Technique 8)

The solder mounting land according to Technique 6 or 7, wherein the plurality of grooves further include a groove extending concentrically in the inside of the first region, and spatially connected with a groove extending radially.

### (Technique 9)

The solder mounting land according to any one of Technique 3 to 5, wherein the plurality of grooves are formed in a lattice pattern.

### (Technique 10)

The solder mounting land according to any one of Techniques 1 to 9, wherein
the first region has a round shape or a rectangular shape, and
the second region protrudes from a part of an outer edge portion of the first region.

### (Technique 11)

The solder mounting land according to any one of Techniques 1 to 9, wherein
the first region has an annular shape that is hollow in plan view, and
the second region protrudes from at least one of an inner edge portion and an outer edge portion of the first region.

### (Technique 12)

The solder mounting land according to any one of Techniques 1 to 9, wherein
the first region has a rectangular shape, and
the second region is provided at least at a part other than corner portions of the first region.

### (Technique 13)

The solder mounting land according to any one of Techniques 1 to 12, wherein, in a peripheral edge portion of the second region, a peripheral edge portion opposite to the first region has a shape following a shape of a corresponding part of the peripheral edge portion of the first region.

### (Technique 14)

The solder mounting land according to any one of Techniques 1 to 13, wherein the second region has a shape corresponding to a size of a fillet to be formed in a peripheral edge portion of the electronic component by the solder.

### (Technique 15)

The solder mounting land according to any one of Techniques 1 to 14, wherein the first region has a shape obtained by extending an outer shape of a bonding surface of the electronic component by a deviation amount of an arrangement position allowed for the electronic component.

### (Technique 16)

A solder mounting land according to the present disclosure is a land on which an electronic component is to be disposed via solder and the electronic component is to be mounted by soldering. The solder mounting land including:

a first region formed by exposing a conductive layer of a substrate from a solder resist layer stacked on an upper surface of the conductive layer, the electronic component being to be bonded to the first region; and

a groove formed by exposing a layer underneath the conductive layer, and extending from an inside to a peripheral edge portion of the first region to divide the first region.

### (Technique 17)

A charger including:
a circuit board provided with the solder mounting land according to any one of Techniques 1 to 16; and

the electronic component mounted on the circuit board by soldering.

What is claimed is:

1. A solder mounting land on which an electronic component is to be disposed via solder and the electronic component is to be mounted by soldering, the solder mounting land comprising:
a first region to which the electronic component is bonded; and
a second region protruding from a part of a peripheral edge portion of the first region in a direction in which the first region is extended in plan view.

2. The solder mounting land according to claim 1, further comprising a groove that extends from an inside to the peripheral edge portion of the first region to divide the first region.

3. The solder mounting land according to claim 1, further comprising:
a plurality of grooves each extending from an inside to the peripheral edge portion of the first region to divide the first region,
wherein the second region protrudes from the peripheral edge portion of the first region between at least one pair of adjacent grooves among the plurality of grooves.

4. The solder mounting land according to claim 3, wherein a groove adjacent to the second region extends from the inside of the first region to a peripheral edge portion of the second region.

5. The solder mounting land according to claim 3, wherein
the first region has an annular shape that is hollow in plan view, and
each of the plurality of grooves radially extends from an inner edge portion to an outer edge portion of the first region.

6. The solder mounting land according to claim 3, wherein
the first region has a round shape, and
each of the plurality of grooves radially extends from a central portion to an outer edge portion of the first region.

7. The solder mounting land according to claim 5, wherein the plurality of grooves further include a groove extending concentrically in the inside of the first region, and spatially connected with a groove extending radially.

8. The solder mounting land according to claim 6, wherein the plurality of grooves further include a groove extending concentrically in the inside of the first region, and spatially connected with a groove extending radially.

9. The solder mounting land according to claim 3, wherein the plurality of grooves are formed in a lattice pattern.

10. The solder mounting land according to claim 1, wherein
the first region has a round shape or a rectangular shape, and
the second region protrudes from a part of an outer edge portion of the first region.

11. The solder mounting land according to claim 1, wherein
the first region has an annular shape that is hollow in plan view, and
the second region protrudes from at least one of an inner edge portion and an outer edge portion of the first region.

12. The solder mounting land according to claim 1, wherein
the first region has a rectangular shape, and
the second region is provided at least at a part other than corner portions of the first region.

13. The solder mounting land according to claim 1, wherein, in a peripheral edge portion of the second region, a peripheral edge portion opposite to the first region has a shape following a shape of a corresponding part of the peripheral edge portion of the first region.

14. The solder mounting land according to claim 1, wherein the second region has a shape corresponding to a size of a fillet to be formed in a peripheral edge portion of the electronic component by the solder.

15. The solder mounting land according to claim 1, wherein the first region has a shape obtained by extending an outer shape of a bonding surface of the electronic component by a deviation amount of an arrangement position allowed for the electronic component.

16. A charger comprising:
a circuit board provided with the solder mounting land according to claim 1; and
the electronic component mounted on the circuit board by soldering.

17. A solder mounting land according to the present disclosure is a land on which an electronic component is to be disposed via solder and the electronic component is to be mounted by soldering. The solder mounting land comprising:
a first region formed by exposing a conductive layer of a substrate from a solder resist layer stacked on an upper surface of the conductive layer, the electronic component being to be bonded to the first region; and
a groove formed by exposing a layer underneath the conductive layer, and extending from an inside to a peripheral edge portion of the first region to divide the first region.
